(19) United States
(12) Patent Application Publication
(10) Pub. No.: US 2006/0111244 A1
(43) Pub. Date: May 25, 2006

(54) Methods for fabricating thin film transistors

(75) Inventors: Feng-Yuan Gan, Hsinchu City (TW); Han-Tu Lin, Taichung County (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/143,698

(22) Filed: Jun. 2, 2005

(30) Foreign Application Priority Data
Nov. 22, 2004 (TW) 93135855

(51) Int. Cl. H01L 39/14

(52) U.S. Cl. 505/193

(57) ABSTRACT

A fabrication method of thin film transistor. A patterned gate is formed on an insulator substrate. A buffer layer is formed on the insulating substrate. The patterned gate is formed by plasma enhanced chemical vapor deposition (PECVD) using a mixture of silane, argon, nitrogen to serve as reactants at a temperature of approximately 20-200° C. A gate insulating layer is formed on the buffer layer. A semiconductor layer is formed on the gate insulating layer. A source/drain layer is formed on the semiconductor layer. The buffer layer protects the metal gate from damage during subsequent plasma enhanced chemical vapor deposition.

### BACKGROUND

The invention relates to methods for fabricating thin film transistors, and more particularly, to methods for fabricating gate structures of thin film transistors.

Bottom-gate type thin film transistors (TFTs) are widely used for thin film transistor liquid crystal displays (TFT-LCDs). FIG. 1 is a sectional view of a conventional bottom-gate type TFT structure 100. The TFT structure 100 typically comprises a glass substrate 110, a metal gate 120, a gate insulating layer 130, a channel layer 140, an ohmic contact layer 150, a source 160 and a drain 170.

As the size of TFT-LCD panels increases, metals having low resistance are required. For example, gate lines employ low resistance metals such as Cu and Cu alloy in order to improve operation of the TFT-LCD. Cu, however, has unstable properties such as poor adhesion to the glass substrate which can cause a film peeling problem. Cu also has a tendency to diffuse into a silicon film and must be mixed with other metals such as Cr or Mg to increase the resistance thereof. Moreover, Cu is vulnerable to deformation. Specifically, in a plasma process of depositing a film, characteristic degradation such as roughness and resistance of Cu are increased due to reaction between Cu and the plasma during plasma enhanced chemical vapor deposition (PECVD).

U.S. Pat. No. 6,165,917 to Batey et al., the entirety of which is hereby incorporated by reference, discloses a method for passivating Cu, using an ammonia-free silicon nitride layer as a cap layer covering a Cu gate.

U.S. Publication No. 2002/0042167 to Chae, the entirety of which is hereby incorporated by reference, discloses a method of forming a TFT, in which a metal layer such as Ta, Cr, Ti or W is deposited on a substrate. A Cu gate is defined on the metal layer. Thermal oxidation is then performed to diffuse the material of the metal layer along the surface of the Cu gate, which is consequently surrounded by a metallic oxide. The metallic oxide comprises tantalum oxide, chrome oxide, titanium oxide or tungsten oxide.

U.S. Pat. No. 6,562,668 to Jang et al., the entirety of which is hereby incorporated by reference, discloses a method of forming a TFT, using aluminum oxide layer or aluminum nitride layer as an adhesion layer between a Cu gate and a glass substrate. A cap layer covers the Cu gate.

### SUMMARY

Accordingly, the invention provides fabrication methods of thin film transistors, utilizing a nitrogen-rich silicon nitride layer as a buffer layer, thereby preventing metal gate damage during subsequent plasma process and preventing the metal gate reaction with ammonia.

The invention provides a method for fabricating a thin film transistor, comprising forming a patterned gate on an insulating substrate, forming a buffer layer on the insulating substrate and the patterned gate by the plasma enhanced chemical vapor deposition (PECVD) using a mixture of silane, argon, nitrogen to serve as reactants at a temperature in a range of approximately 20-200° C., forming a gate insulating layer on the gate, forming a semiconductor layer on the gate insulating layer, and forming a source and a drain on a portion of the semiconductor layer.

### DESCRIPTION OF THE DRAWINGS

The invention can be more fully understood by reading the subsequent detailed description in conjunction with the examples and references made to the accompanying drawings, wherein

FIG. 1 is a sectional view of a conventional bottom-gate type TFT structure; and

FIGS. 2A-2D are cross sections of an exemplary embodiment of methods for fabricating a thin film transistor.

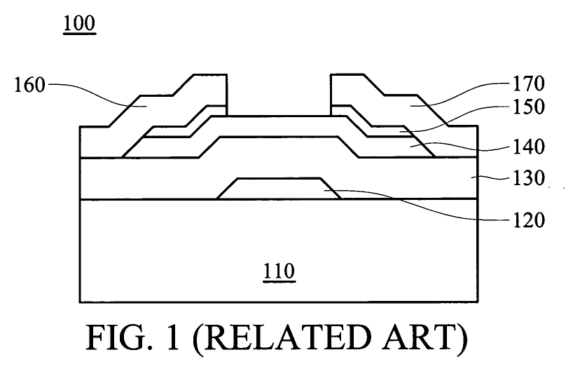

### DETAILED DESCRIPTION

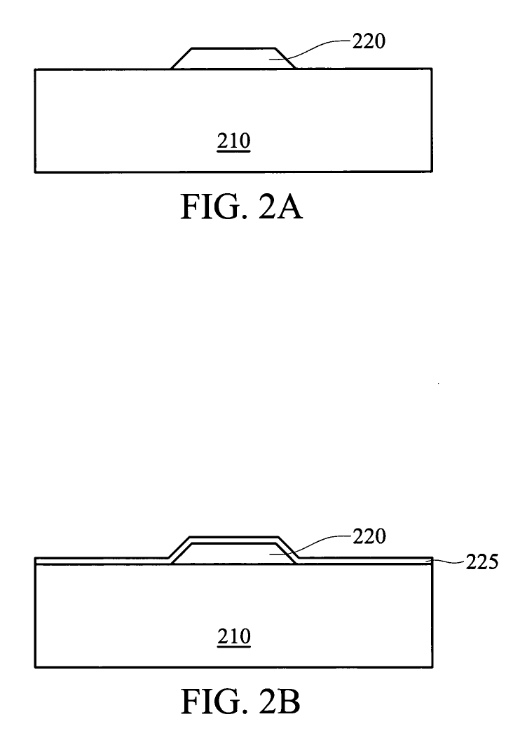

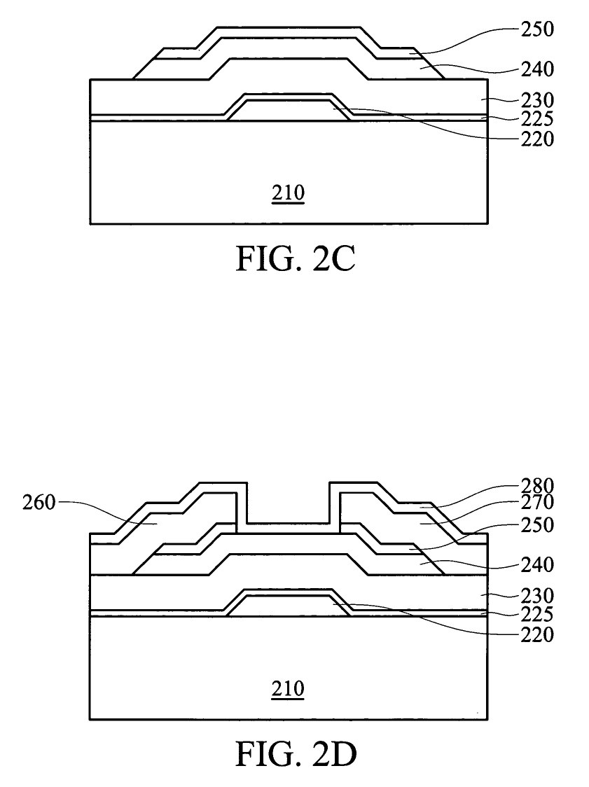

Thin film transistors (TFTs) and fabrication methods thereof are provided. The thin film transistors can be bottom-gate type TFTs, top-gate type TFTs or others. For convenience, representative bottom-gate type TFT structures are illustrated, but are not intended to limit the disclosure. FIGS. 2A-2D are cross sections of an exemplary embodiment of methods for fabricating a thin film transistor.

Referring to FIG. 2A, a metal layer 220 is formed on an insulating substrate 210. The metal layer 220 can comprise, for example, Al, Mo, Cr, W, Ta, Cu, Ag, Ag—Pd—Cu, or alloys thereof deposited by sputtering. The substrate 210 can comprise glass, quartz or transparent plastic substrate. The metal layer 220 is patterned by conventional lithography and etching to form a metal gate 220. Patterning of the metal layer 220 comprises etching the metal layer 220 to form tapered sidewalls. The tapered sidewalls provide excellent step-coverage for subsequent layer formation. Note that an adhesion layer (not shown) can optionally be formed between the metal layer 220 and the insulating substrate 210, thereby improving adhesion between the metal gate 220 and the insulating substrate 210.

Referring to FIG. 2B, a buffer layer 225 is formed over the insulating layer 210. The buffer layer 225 is formed by, for example, plasma enhanced chemical vapor deposition (PECVD) at relatively low temperature and by controlling mix ratio of processing gas. The insulating substrate 210 is positioned in a CVD chamber, and processing gas comprising, for example, silane, argon, or nitrogen is introduced. The mix ratio of the processing gas, a nitrogen-rich silicon nitride 225 is controlled. The stoichiometric ratio of nitrogen to silicon of the buffer layer 225 exceeds 3:4. The mix ratio of silane to nitrogen is controlled at 1:5 and the reaction temperature is in a range of approximately 20-200° C. The thickness of the nitrogen rich silicon nitride layer 225 is in a range of approximately 50-200 Å.

Referring to FIG. 2C, a gate insulating layer 230 is subsequently formed over the insulating substrate 210 covering the metal gate 220 and the buffer layer 225. The gate insulating layer 230 can be formed by, for example, plasma enhanced chemical vapor deposition (PECVD). The gate insulating layer 230 can comprise silicon oxide, silicon nitride, silicon oxynitride, tantalum oxide or aluminum oxide.

Referring to FIG. 2C again, a silicon-containing semiconductor layer 240 is formed on the gate insulating layer 230, comprising polysilicon, amorphous silicon, or impurity-added silicon formed by CVD. An ohmic contact layer 250 can optionally be formed on the silicon-containing semiconductor layer. The silicon-containing semiconductor 240 and the ohmic contact layer 250 are patterned by conventional lithography and etching to form a channel 240 and the ohmic contact layer 250. The ohmic contact layer 250 can comprise n-type doped silicon, for example, phosphorous-doped or arsenide-doped silicon.

Referring to FIG. 2D, a metal layer is formed on the ohmic contact layer 250 and the gate insulating layer 230, comprising Al, Mo, Cr, W, Ta, Ti, Ni, or combinations thereof, by sputtering. The metal layer is patterned to form a source 260 and a drain 270 exposing the ohmic contact layer 250. The exposed ohmic contact layer 250 is etched using the source 260 and the drain 270 as masks. Next, a passivation layer 280 is conformably formed over the insulating substrate 210. A thin film transistor is thus formed.

Note that when the TFT structure is applied in a thin film transistor liquid crystal display panel, the metal gate stack structure 220 and the gate line (not shown) of an array substrate can be formed simultaneously. Thus, the first doped metal layer 222 can also be disposed between the gate line and the insulating substrate 210. To avoid obscuring aspects of the disclosure, description of detailed formation of the TFT-LCD panel is omitted here.

While the invention has been described by way of example and in terms of preferred embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method for fabricating a thin film transistor, comprising:
forming a patterned gate on an insulating substrate;
forming a buffer layer on the insulating substrate and the patterned gate by plasma enhanced chemical vapor deposition (PECVD) using a mixture of silane, argon, nitrogen to serve as reactants at a temperature of approximately 20-200° C.;
forming a gate insulating layer on the gate;
forming a semiconductor layer on the gate insulating layer; and
forming a source and a drain on a portion of the semiconductor layer.

2. The method as claimed in claim 1, wherein the buffer layer comprises a nitrogen-rich silicon nitride.

3. The method as claimed in claim 1 or 2, wherein the stoichiometric ratio of nitrogen to silicon of the buffer layer is greater than ¾.

4. The method as claimed in claim 1, wherein the substrate comprises glass or quartz.

5. The method as claimed in claim 1, wherein the gate comprises Cu, Al, Mo, Cr, W, Ta, Ag, Ag—Pd—Cu, or alloys thereof.

6. The method as claimed in claim 1, wherein the gate insulating layer comprises a silicon oxide, a silicon nitride, a silicon oxynitride, a tantalum oxide or an aluminum oxide.

7. The method as claimed in claim 1, wherein the semiconductor layer comprises polysilicon or amorphous silicon deposited by PECVD.

8. The method as claimed in claim 1, wherein the source and the drain comprise Al, Mo, Cr, W, Ta, Ti, Ni, or alloys thereof.

9. The method as claimed in claim 1, further comprising forming a passivation layer over the insulating layer.
